(19) United States
(12) Patent Application Publication
(10) Pub. No.: US 2025/0364516 A1
(43) Pub. Date: Nov. 27, 2025

(54) SEMICONDUCTOR PACKAGE

(71) Applicant: Samsung Electronics Co., Ltd., Suwon-si (KR)

(72) Inventors: Wansun Kim, Suwon-si (KR); Shlege Lee, Suwon-si (KR); Insik Han, Suwon-si (KR)

(21) Appl. No.: 18/953,304

(22) Filed: Nov. 20, 2024

(30) Foreign Application Priority Data
May 23, 2024 (KR) 10-2024-0067234

(51) Int. Cl. H01L 25/18; H01L 23/00; H01L 23/31; H01L 23/498; H01L 23/538; H10B 80/00

(52) U.S. Cl. CPC H01L 25/18; H01L 23/49816; H01L 23/5385; H01L 23/562; H01L 23/3107; H10B 80/00

(57) ABSTRACT

A semiconductor package includes a first lower interconnection structure, a first semiconductor chip electrically connected to the first lower interconnection layer, a first encapsulant covering at least a portion of each of the first semiconductor chip, a second lower interconnection structure disposed on the first encapsulant, an upper interconnection structure disposed on the second lower interconnection structure, a second semiconductor chip electrically connected to the upper interconnection layer, a plurality of third semiconductor chips spaced apart from the second semiconductor chip in a horizontal direction, on the upper interconnection structure. The upper interconnection structure has a central region overlapping the first semiconductor chip in a vertical direction, and an outer region disposed around the central region. Each of the plurality of third semiconductor chips has a first portion positioned in the central region, and a second portion positioned in the outer region.

### CROSS-REFERENCE TO RELATED APPLICATION(S)

This application claims benefit of priority to Korean Patent Application No. 10-2024-0067234 filed on May 23, 2024 in the Korean Intellectual Property Office, the disclosure of which is incorporated herein by reference in its entirety.

### BACKGROUND

The present inventive concept relates to a semiconductor package.

With reductions in weight and the implementation of high performance in electronic devices, the development of semiconductor packages, having a reduced size and high performance, has been required. In a structure in which a plurality of packages are vertically stacked, various issues may occur due to a difference between coefficients of thermal expansion occurring when a plurality of materials are mounted in a single package.

### SUMMARY

An aspect of the present inventive concept provides a semiconductor package having improved reliability.

According to an aspect of the present inventive concept, there is provided a semiconductor package including a first lower interconnection structure including a first lower interconnection layer, a first semiconductor chip disposed on the first lower interconnection structure, the first semiconductor chip electrically connected to the first lower interconnection layer, a connection structure disposed around the first semiconductor chip, the connection structure electrically connected to the first lower interconnection layer, a first encapsulant covering at least a portion of each of the first semiconductor chip and the connection structure, a second lower interconnection structure disposed on the first encapsulant, the second lower interconnection structure including a second lower interconnection layer electrically connected to the connection structure, an upper interconnection structure disposed on the second lower interconnection structure, the upper interconnection structure including an upper interconnection layer, solder bumps disposed between the second lower interconnection structure and the upper interconnection structure, the solder bumps electrically connecting the second lower interconnection layer and the upper interconnection layer to each other, a second semiconductor chip disposed on the upper interconnection structure, the second semiconductor chip electrically connected to the upper interconnection layer, a plurality of third semiconductor chips spaced apart from the second semiconductor chip in a horizontal direction, on the upper interconnection structure, and a second encapsulant covering at least a portion of each of the second semiconductor chip and the plurality of third semiconductor chips. The first semiconductor chip may have a first planar area. The second semiconductor chip may have a second planar area, smaller than the first planar area. Each of the plurality of third semiconductor chips may have a third planar area, smaller than the second planar area. The upper interconnection structure may have a central region overlapping the first semiconductor chip in a vertical direction, and an outer region disposed around the central region. Each of the plurality of third semiconductor chips may have a first portion positioned in the central region, and a second portion positioned in the outer region.

According to another aspect of the present inventive concept, there is provided a semiconductor package including a first lower interconnection structure including a first lower interconnection layer, a first semiconductor chip disposed on the first lower interconnection structure, a connection structure disposed around the first semiconductor chip, the connection structure electrically connected to the first lower interconnection layer, a second lower interconnection structure including a second lower interconnection layer electrically connected to the connection structure, on the first lower interconnection structure, an upper interconnection structure including an upper interconnection layer and upper connection pads electrically connected to the upper interconnection layer, a plurality of chip stacks disposed on the upper interconnection structure to be spaced apart from each other in a first direction, the plurality of chip stacks including chip connection pads, and a bonding wire connecting, to each other, the upper connection pads and the chip connection pads adjacent to each other in a second direction, intersecting the first direction, the bonding wire extending in the second direction. Each of the plurality of chip stacks may be disposed to be misaligned with the first semiconductor chip in at least one of the first direction and the second direction.

According to another aspect of the present inventive concept, there is provided a semiconductor package including a first lower interconnection structure, a semiconductor chip mounted on the first lower interconnection structure, an encapsulant covering at least a portion of the semiconductor chip, on the first lower interconnection structure, a second lower interconnection structure disposed on the encapsulant, an upper interconnection structure disposed on the second lower interconnection structure, the upper interconnection structure electrically connected to the second lower interconnection structure, and a plurality of chip structures mounted on the upper interconnection structure. At least one chip structure, among the plurality of chip structures, may overlap at least one corner, among corners of the semiconductor chip, in a vertical direction.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a top view of a semiconductor package according to an example embodiment of the present inventive concept;

FIG. 2A is a cross-sectional view of the semiconductor package of FIG. 1, taken along line I1-I1′, and FIG. 2B is a cross-sectional view of the semiconductor package of FIG. 1, taken along line I2-I2′;

FIG. 3 is a top view of a semiconductor package according to an example embodiment of the present inventive concept;

FIG. 4 is a cross-sectional view of the semiconductor package of FIG. 3, taken along line II-II′;

FIG. 5 is a top view of a semiconductor package according to an example embodiment of the present inventive concept;

FIG. 6 is a top view of a semiconductor package according to an example embodiment of the present inventive concept;

FIG. 7 is a cross-sectional view of the semiconductor package of FIG. 6 taken along line III-III′;

FIG. 8 is a top view of a semiconductor package according to an example embodiment of the present inventive concept;

FIG. 9 is a cross-sectional view of the semiconductor package of FIG. 8, taken along line IV-IV′;

FIGS. 10 to 12 are cross-sectional views of a semiconductor package having an issue in which cracks occur after a solder bump formation process; and

FIG. 13 is a cross-sectional view of a semiconductor package having improved reliability according to an example embodiment of the present inventive concept.

### DETAILED DESCRIPTION

Hereinafter, preferred example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually arranged.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, embodiments in the example embodiment will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

An item, layer, or portion of an item or layer described as extending “lengthwise” in a particular direction has a length in the particular direction and a width perpendicular to that direction, where the length is greater than the width.

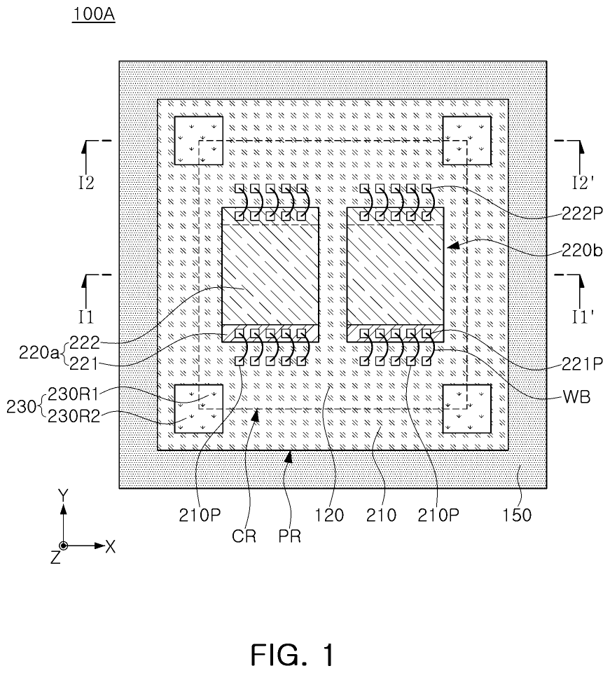

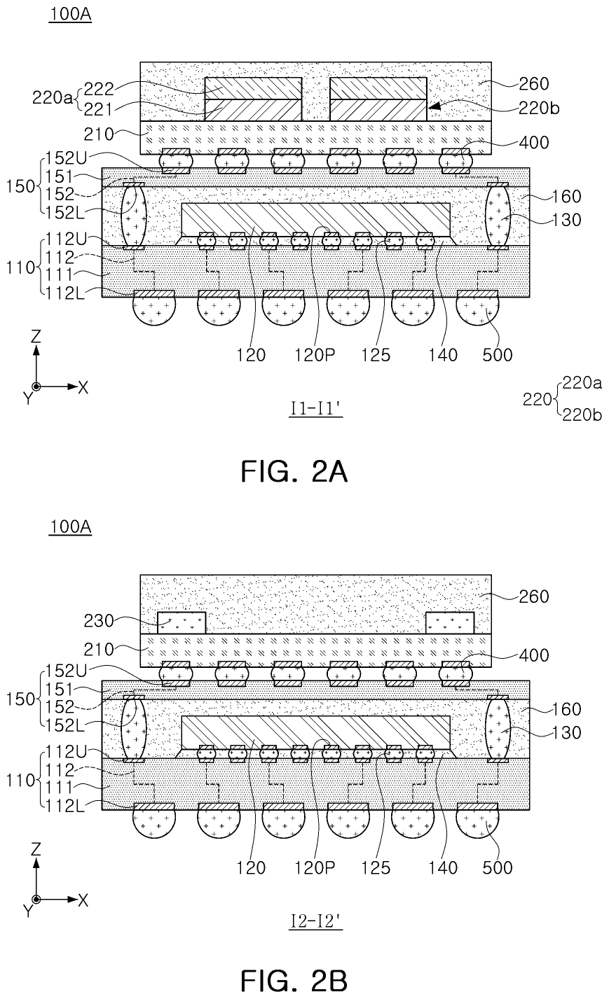

FIG. 1 is a top view of a semiconductor package according to an example embodiment of the present inventive concept. FIG. 2A is a cross-sectional view of the semiconductor package of FIG. 1, taken along line I1-I1′, and FIG. 2B is a cross-sectional view of the semiconductor package of FIG. 1, taken along line I2-I2′.

Referring to FIGS. 1, 2A, and 2B, a semiconductor package 100A according to an example embodiment may include a first lower interconnection structure 110, a first semiconductor chip 120, a first encapsulant 160, a second lower interconnection structure 150, an upper interconnection structure 210, a solder bump 400, a set of second semiconductor chips 220, a plurality of third semiconductor chips 230 (e.g., dummy chips), and a second encapsulant 260. For example, the various interconnection structures may interconnect semiconductor devices within semiconductor package 100A so as to provide logical circuitry and communication. Referring to FIGS. 1, 2A, and 2B, the semiconductor package 100A according to an example embodiment may further include connection structures 130 (e.g., vias or interconnection terminals) and an external connection conductor 500 (e.g., an external connection terminal).

The first lower interconnection structure 110 may include a first lower insulating layer 111 and a first lower interconnection layer 112. The first lower interconnection structure 110 may further include a via structure electrically connecting, to each other, first lower interconnection layers 112 disposed on different levels. The first lower interconnection structure 110 may be a substrate for a semiconductor package (i.e., a package substrate) including a printed circuit board (PCB), a ceramic substrate, a glass substrate, a tape interconnection substrate, or the like. For example, the substrate may be a package substrate that includes the first lower insulating layer 111 and the first lower interconnection layer 112, which forms an electrical path within the lower insulating layer 111, as described below.

The first lower insulating layer 111 may include an insulating resin. The insulating resin may include a thermosetting resin such as an epoxy resin, a thermoplastic resin such as polyimide, or a resin, for example, a prepreg, an Ajinomoto build-up film (ABF), FR-4, or Bismaleimide Triazine (BT), in which the thermosetting resin or the thermoplastic resin is impregnated with an inorganic filler and/or a glass fiber (or glass cloth or glass fabric). The insulating resin may also include a photosensitive resin such as a photoimageable dielectric (PID) resin. For example, when the first lower interconnection structure 110 is a PCB, the first lower insulating layer 111 may be a core insulating layer (for example, a prepreg) of a copper foil laminate. The first lower insulating layer 111 may have a form in which a large number of insulating layers are stacked in a vertical direction (for example, a Z-axis direction), and first insulating layers on different levels may have unclear boundaries therebetween, depending on a process.

The first lower interconnection layer 112 may be disposed in the first lower insulating layer 111, and may form an electrical path in the first lower interconnection structure 110. The first lower interconnection layer 112 may include at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C). The first lower interconnection layer 112 may be a plurality of interconnection layers, positioned on different levels, among a plurality of insulating layers.

Upper pads 112U may be disposed on or at an upper surface of the first lower insulating layer 111, and lower pads 112L may be disposed on or at a lower surface of the first lower insulating layer 111. The upper pads 112U and the lower pads 112L may be electrically connected through the first lower interconnection layer 112. The upper pads 112U may be electrically connected to the first semiconductor chip 120 through connection structures (e.g., interconnection terminals), on the first lower insulating layer 111, and the lower pads 112L may be electrically connected to a plurality of external connection conductors 500 (e.g., external connection terminals), below the first lower insulating layer 111. The upper pads 112U and the lower pads 112L may include a material the same as that of an interconnection circuit, but the present inventive concept is not limited thereto. In an example embodiment, the upper pads 112U may include at least one metal or an alloy including two or more metals, among copper (Cu), nickel (Ni), and gold (Au), but the present inventive concept is not limited thereto.

The first semiconductor chip 120 may be disposed on an upper surface of the first lower interconnection structure 110. The first semiconductor chip 120 may be disposed to be adjacent to or positioned at a center of the first lower interconnection structure 110, but the present inventive concept is not limited thereto. The first semiconductor chip 120 may include first chip connection pads 120P disposed at a bottom of the first semiconductor chip 120 (e.g., at a bottom surface of the first semiconductor chip 120). The first chip connection pads 120P may be disposed to be vertically aligned with the upper pads 112U of the first lower interconnection structure 110. First conductive bumps 125 may be disposed between the first chip connection pads 120P and the upper pads 112U. The first conductive bumps 125 may include a conductive material, for example, tin (Sn) or an alloy (Sn—Ag—Cu) including tin (Sn). The first conductive bumps 125 may electrically connect, the first chip connection pads 120P of the first semiconductor chip 120 to the upper pads 112U of the first lower interconnection structure 110. A first underfill material 140, covering at least a portion of each of the first semiconductor chip 120 and the first conductive bumps 125, may be disposed between the first semiconductor chip 120 and the first lower interconnection structure 110.

The first semiconductor chip 120 may be an integrated circuit (IC) that is in a bare state in which no separate bump or interconnection layer is formed. For example, the first semiconductor chip 120 may be a die formed from a wafer. However, the present inventive concept is not limited thereto, and in some embodiments, instead of the first semiconductor chip 120, a packaged-type integrated circuit device (e.g., a semiconductor package) may be disposed. The integrated circuit may be a processor chip such as a central processor CPU, a graphic processor GPU, a field programmable gate array FPGA, an application processor AP, a digital signal processor, a cryptographic processor, a microprocessor, a microcontroller, or the like, but the present inventive concept is not limited thereto, and may be a logic chip such as an analog-to-digital converter, an application-specific IC (ASIC), or the like. The first semiconductor chip 120 may have a square shape in plan view, but the present inventive concept is not limited thereto, and may have a first plan area.

The connection structures 130 may be disposed around the first semiconductor chip 120, on the first lower interconnection structure 110. A vertical connection path (e.g., formed from the connection structures 130) may be disposed between the first lower interconnection structure 110 and the second lower interconnection structure 150, and may electrically connect, to each other, the first lower interconnection layer 112 and the second lower interconnection layer 152. The connection structure 130 may have, for example, a spherical or ball shape formed of a low melting point metal such as Sn, indium (In), bismuth (Bi), antimony (Sb), copper (Cu), silver (Ag), zinc (Zn), lead (Pb), or an alloy (for example, Sn—Ag—Cu) including the same or a pillar shape having a convex middle portion, but the present inventive concept is not limited thereto.

The first encapsulant 160 may cover at least a portion of each of the first semiconductor chip 120 and the connection structures 130, on the first lower interconnection structure 110, and may protect and/or insulate these components. The first encapsulant 160 may cover an upper surface of the first semiconductor chip 120, and the first encapsulant 160 may cover a side surface of the connection structures 130. An upper surface of the first encapsulant 160 may be substantially coplanar with an upper surface of the connection structures 130. The first encapsulant 160 may include an insulating resin, for example, a thermosetting resin such as an epoxy resin, a thermoplastic resin such as polyimide, or a prepreg, an ABF, FR-4, BT, or an epoxy molding compound (EMC). For example, the first encapsulant 160 may include a filler dispersed in the insulating resin, but the present inventive concept is not limited thereto.

The second lower interconnection structure 150 may be disposed on the first encapsulant 160. The second lower interconnection structure 150 may include a second lower insulating layer 151, and a second lower interconnection layer 152 electrically connected to the connection structure 130 in the second lower insulating layer 151. The second lower insulating layer 151 and the second lower interconnection layer 152 may have features the same as or similar to those of the first lower insulating layer 111 and the first lower interconnection layer 112 described above, and thus a repeated description will be omitted. The second lower insulating layer 151 and the second lower interconnection layer 152 may together form a substrate, and may be described as an interposer substrate. The second lower interconnection structure 150 may have a width the same as those of the first lower interconnection structure 110 and the first encapsulant 160 in a first direction (for example, an X-axis direction), but the present inventive concept is not limited thereto. The second lower interconnection structure 150 may have a planar area the same as those of the first lower interconnection structure 110 and the first encapsulant 160, but the present inventive concept is not limited thereto.

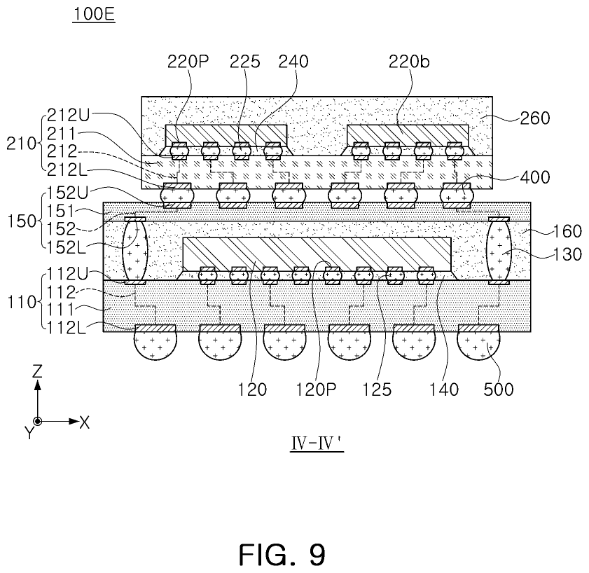

The upper interconnection structure 210 may be disposed on the second lower interconnection structure 150. The upper interconnection structure 210 may have a width less than those of the first and second lower interconnection structures 110 and 150 in the first direction (for example, an X-axis direction). The upper interconnection structure 210 may be aligned such that central portions (e.g., a center) of the first and second lower interconnection structures 110 and 150 and central portions (e.g., a center) of the upper interconnection structure 210 are aligned in a direction (for example, a Z-axis direction), perpendicular to an upper surface of the upper interconnection structure 210. The upper interconnection structure 210 may include an upper insulating layer 211 and an upper interconnection layer 212 (see FIG. 9). The upper insulating layer 211 and the upper interconnection layer 212 may have features the same as or similar to those of the first lower insulating layer 111 and the first lower interconnection layer 112 described above, and thus repeated descriptions will be omitted. The upper interconnection structure 210 may be a substrate on which second semiconductor chips 220 are mounted, and may be an additional package substrate.

The upper interconnection structure 210 may have a central region CR overlapping the first semiconductor chip 120 in a vertical direction (e.g., in plan view, as shown in FIG. 1), and an outer region PR disposed around the central region CR. The central region CR may have a shape the same as a planar shape of the first semiconductor chip 120, for example a square shape, but the present inventive concept is not limited thereto. The outer region PR may be disposed along a circumference of the central region CR, and may have a rectangular ring shape, but the present inventive concept is not limited thereto. In some embodiments, the outer boundary of the first semiconductor chip 120 is the boundary between the outer region PR and the central region CR.

The upper interconnection structure 210 may include upper connection pads 210P disposed on one side of the upper surface of the upper interconnection structure 210. In an example embodiment, the upper connection pads 210P may be arranged in the first direction (for example, an X-axis direction).

The solder bumps 400 may be disposed between the second lower interconnection structure 150 and the upper interconnection structure 210. The solder bumps 400 may be electrically connected to the second lower interconnection layer 152 and the upper interconnection layer 212. In some examples, the solder bumps 400 may include a combination of a pillar (or under-bump metal) and a ball. For example, the pillar may include copper (Cu) or an alloy of copper (Cu), and the ball may include a low melting point metal, for example, tin (Sn) or an alloy (Sn—Ag—Cu) including tin (Sn). The solder bumps 400 may be disposed in a region defined by the upper interconnection structure 210.

The second semiconductor chips 220 may be disposed on the upper interconnection structure 210, and the second semiconductor chips 220 may be electrically connected to the upper interconnection layer 212. The second semiconductor chips 220 may be disposed in the central region CR of the upper interconnection structure 210, but the present inventive concept is not limited thereto. The second semiconductor chips 220 may overlap the first semiconductor chip 120 in the vertical direction (for example, a Z-axis direction). The second semiconductor chips 220 may be in the form of one or more chip stacks in which a plurality of semiconductor chips 221 and 222 are stacked in the vertical direction. The second semiconductor chips 220 may be in the form of being offset-aligned in one direction (for example, a Y-axis direction) such that side surfaces of adjacent ones of each of a plurality of semiconductor chips do not correspond to each other. For example, the semiconductor chips in each chip stack may be stacked in a step configuration. The second semiconductor chips 220 may include a plurality of chip stacks 220a and 220b spaced apart from each other in the first direction (for example, an X-axis direction). In plan view, the plurality of chip stacks 220 may be disposed on or within a first boundary defined by sides of the first semiconductor chip 120.

The second semiconductor chips 220 may include chip connection pads 221P and 222P disposed on one side of an upper surface of the second semiconductor chips 220. In an example embodiment, the chip connection pads 221P and 222P may be disposed to be aligned in the first direction (for example, an X-axis direction). The chip connection pads 221P and 222P may include chip connection pads 221P disposed on an upper surface of the second semiconductor chip 221 disposed on a lower portion of the chip stack, and chip connection pads 222P disposed on an upper surface of the second semiconductor chip 222 disposed on an upper portion of the chip stack. The chip connection pads 221P of the lower second semiconductor chip 221 may be disposed on at least a portion of an upper surface exposed from the upper second semiconductor chip 222. Each of the second semiconductor chips 220 may be a memory chip such as a volatile memory (for example, DRAM), a non-volatile memory (for example, ROM and flash memory), and may be a memory chip stack in which a plurality of memory chips are stacked in the vertical direction. Each of the second semiconductor chips 220 may have a second planar area, smaller than a first planar area of the first semiconductor chip 120, but the present inventive concept is not limited thereto.

The chip connection pads 221P and 222P may be disposed to be aligned with the upper connection pads 210P adjacent to each other in a second direction (for example, a Y-axis direction), and the chip connection pads 221P and 222P may be electrically connected to the corresponding upper connection pads 210P through bonding wires WB, respectively. The bonding wires WB may be disposed to extend in the second direction.

The plurality of third semiconductor chips 230 (e.g., dummy chips) may be disposed on the upper interconnection structure 210 to be spaced apart from the second semiconductor chips 220 in a horizontal direction. The plurality of third semiconductor chips 230 may be disposed on a corner portion (e.g., a corner) of the central region CR overlapping the first semiconductor chip 120 (e.g., when viewed from a plan view, such as in FIG. 1). Each of the plurality of third semiconductor chips 230 may include a first portion 230R1 positioned in the central region CR, and a second portion 230R2 positioned in the outer region PR. Each of the plurality of third semiconductor chips 230 may overlap solder bumps 400 disposed on an outermost side of the solder bumps 400 in the vertical direction. The plurality of third semiconductor chips 230 may be shifted outwardly from the central region CR overlapping the first semiconductor chip 120 in the vertical direction (for example, a Z-axis direction). In plan view, a plurality of dummy chips 230 may be disposed on a second boundary defined by vertices of the first semiconductor chip 120. For example, each dummy chip of the plurality of dummy chips 230 may be positioned, from a plan view, to cover a corner of the first semiconductor chip 120 where two side surfaces of the first semiconductor chip 120 meet. Part of the dummy chip may overlap the first semiconductor chip 120 and part of the dummy chip may not overlap the semiconductor chip, from the plan view.

The plurality of third semiconductor chips 230 may be a plurality of dummy chips. For example, such dummy chips may not be intended to function as processors, but may be placed so as to alleviate degrees of thermal expansion of the upper and lower packages, as described herein below. The plurality of third semiconductor chips 230 may be formed of a material including silicon (Si), but the present inventive concept is not limited thereto. The plurality of third semiconductor chips 230 may be electrically insulated from the upper interconnection structure 210. In one embodiment, the plurality of third semiconductor chips do not have integrated circuits formed thereon, for example each may be a silicon die formed from a silicon wafer. Each of the plurality of third semiconductor chips 230 may have a third planar area, smaller than the second planar area of the second semiconductor chips 220, but the present inventive concept is not limited thereto. A thickness of each of the plurality of third semiconductor chips 230 may be greater than or equal to that of a lower second semiconductor chip 221, among the second semiconductor chips 220. The thickness of each of the plurality of third semiconductor chips 230 may be 0.1 mm or more (for example, between 0.1 mm and 0.5 cm), but the present inventive concept is not limited thereto.

A lower package on which the first semiconductor chip 120 is mounted, and an upper package on which the second semiconductor chips 220 is mounted may be formed of different materials having different thermal expansion properties, and may have different dimensions such as sizes and thicknesses of chips, and thus may have different coefficients of thermal expansion (CTE). Due to the above-described difference between the coefficients of thermal expansion, the lower package and the upper package may have a varying degree of expansion or a varying direction of expansion when high-temperature heat is applied, which may apply stress to the solder bumps 400 disposed between the upper and lower packages. Such an issue may be increased for the solder bumps 400 disposed to be adjacent to a corner portion of the upper interconnection structure 210. FIG. 12, described further below, shows an example of a conventional device where different CTEs cause warping of a semiconductor package.

In an example embodiment of the present inventive concept, a structure may be introduced in which at least a portion of the plurality of third semiconductor chips 230 is disposed on the corner portion of the central region CR, such that degrees of thermal expansion of the upper and lower packages may be alleviated, thereby preventing cracks occurring in the solder bumps 400 disposed adjacent to the corner portion below the upper interconnection structure 210. Accordingly, the disclosed structure, including third semiconductor chips 230, can enhance reliability, longevity, and performance of the semiconductor package 100A. Each of the plurality of third semiconductor chips 230 may be disposed to overlap at least a portion of the solder bumps 400, disposed to be adjacent to the corner portion of the central region CR, in the vertical direction.

The second encapsulant 260 may cover at least a portion of each of the second semiconductor chips 220 and the plurality of third semiconductor chips 230, on the upper interconnection structure 210. The second encapsulant 260 may have features the same as or similar to those of the first encapsulant 160 described above, and thus repeated descriptions will be omitted.

The external connection conductors 500 may be disposed below the first lower interconnection structure 110. The external connection conductors 500 may be electrically connected to the first lower interconnection layer 112. The semiconductor package 100A may be connected to an external device such as a module substrate, a system board, or the like through the external connection conductors 500. The external connection conductors 500 may include a combination of a pillar (or under-bump metal) and a ball. For example, the pillar may include copper (Cu) or an alloy of copper (Cu), and the ball may include a low melting point metal, for example, tin (Sn) or an alloy (Sn—Ag—Cu) including tin (Sn). In some example embodiments, the external connection conductors 500 may include the pillar or the ball only. In some example embodiments, a resist layer (not illustrated) may be formed on a lower surface of a lower redistribution structure 310 to protect the external connection conductors 500 from physical and chemical damage.

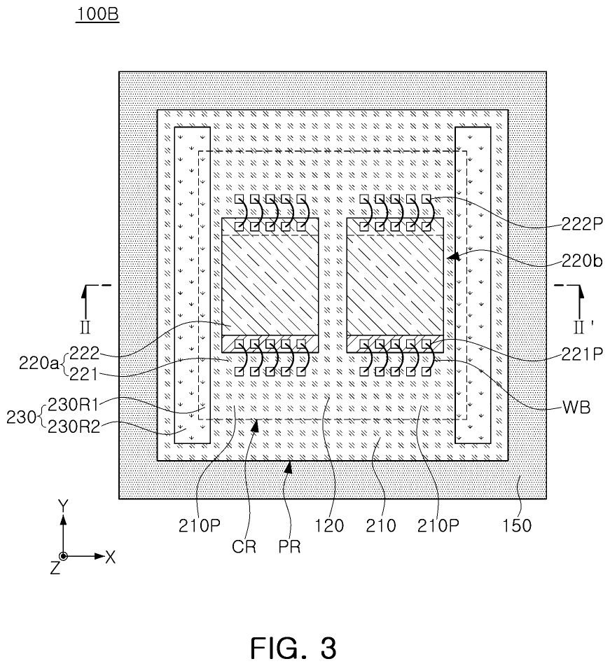

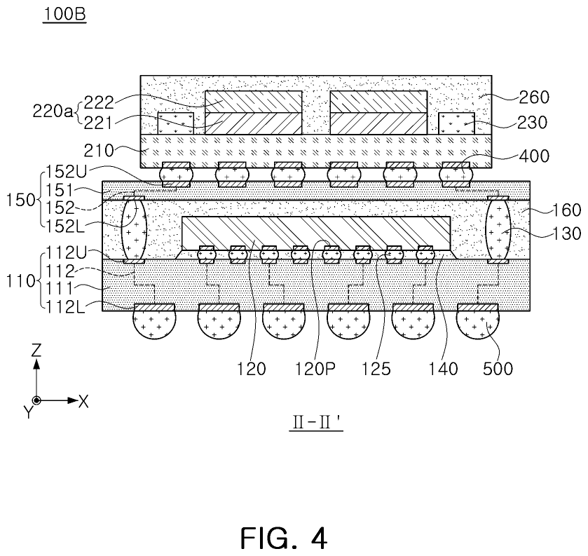

FIG. 3 is a top view of a semiconductor package 100B according to an example embodiment of the present inventive concept. FIG. 4 is a cross-sectional view of the semiconductor package 100B of FIG. 3, taken along line II-II′.

Referring to FIGS. 3 and 4, the semiconductor package 100B according to an example embodiment may have features the same as or similar to those described with reference to FIGS. 1 to 2B, except that a third semiconductor chip 230 extends in one direction.

In this example, the third semiconductor chip 230 may extend lengthwise in a second direction (for example, a Y-axis direction). The third semiconductor chip 230 may have a long bar shape (e.g., a rectangle with length along the second direction), but the present inventive concept is not limited thereto. The third semiconductor chip 230 may be disposed on corner portions of a central region CR of an upper interconnection structure 210. The third semiconductor chip 230 may include a first portion 230R1 positioned in the central region CR, and a second portion 230R2 positioned in the outer region PR. The first portion 230R1 of the third semiconductor chip 230 may overlap a first semiconductor chip 120 in a vertical direction (for example, a Z-axis direction), and the second portion 230R2 of the third semiconductor chip 230 may not overlap the first semiconductor chip 120 in the vertical direction (for example, a Z-axis direction). The third semiconductor chip 230 may extend to be parallel to a direction (for example, a Y-axis direction) in which a bonding wire extends, but the present inventive concept is not limited thereto.

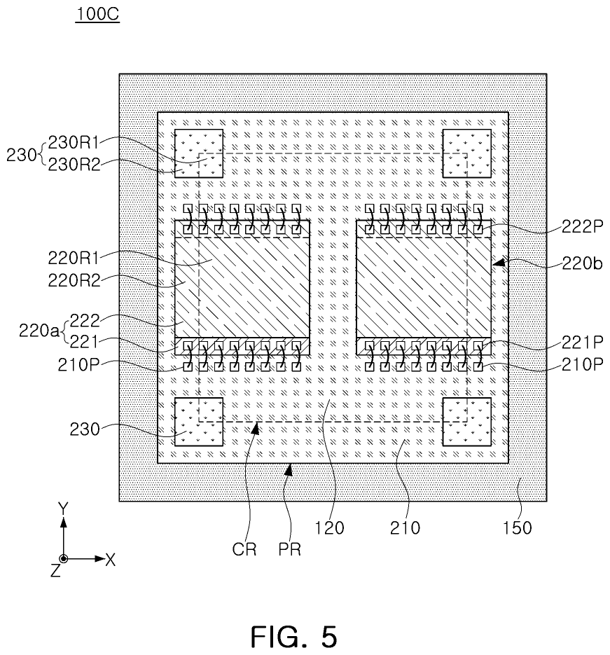

FIG. 5 is a top view of a semiconductor package 100C according to an example embodiment of the present inventive concept.

Referring to FIG. 5, the semiconductor package 100C according to an example embodiment may have features the same as or similar to those described with reference to FIGS. 1 to 4, except that each of second semiconductor chips 220 includes a first portion 220R1 disposed in a central region CR, and a second portion 220R2 disposed in an outer region.

The second semiconductor chips 220 may be in the form of a chip stack in which a plurality of memory chips are stacked in a vertical direction (for example, a Z-axis direction). At least a portion of each of second semiconductor chips 220 may protrude outwardly from a central region CR of an upper interconnection structure 210. The second semiconductor chips 220 may overlap at least a portion of edge portions of the central region CR, overlapping a first semiconductor chip 120 in the vertical direction. In some examples, overlapping at least a portion of edge portions of the central region CR may refer to, for one or more of the edge portions, overlapping only a portion of the central region CR at the edge of the central region CR without overlapping the entire central region CR. However, the present inventive concept is not limited thereto.

Each of second semiconductor chips 220 may include a first portion 220R1 disposed in the central region CR, and a second portion 220R2 disposed in the outer region. The first portion 220R1 may overlap the first semiconductor chip 120 in the vertical direction, and the second portion 220R2 may not overlap the first semiconductor chip 120 in the vertical direction. Based on the above arrangement, the second semiconductor chips 220 may be disposed to be misaligned with the central region CR in a first direction (for example, an X-axis direction), so that they are at least partly outside of the central region CR, but the present inventive concept is not limited thereto, and may be disposed to be misaligned in a second direction (for example, a Y-axis direction).

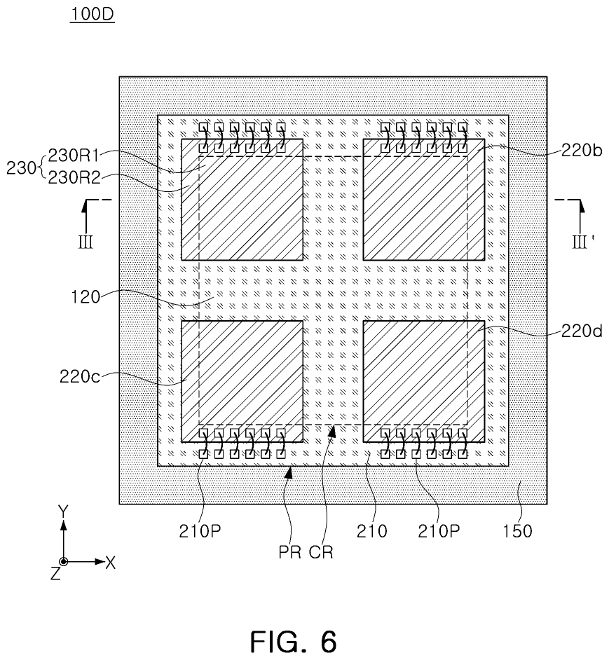

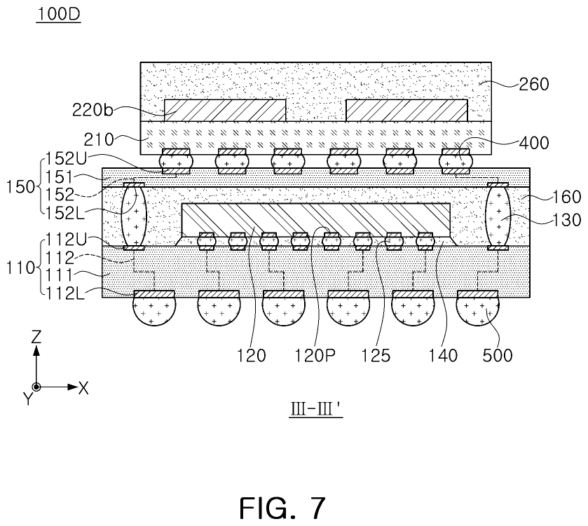

FIG. 6 is a top view of a semiconductor package 100D according to an example embodiment of the present inventive concept. FIG. 7 is a cross-sectional view of the semiconductor package 100D of FIG. 6 taken along line III-III′.

Referring to FIGS. 6 and 7, the semiconductor package 100D according to an example embodiment may have features the same as or similar to those described with reference to FIGS. 1 to 5, except that second semiconductor chips 220 are disposed on corner portions of a central region CR. In addition, in some embodiments, the example of FIGS. 6 and 7 may not include a plurality of third semiconductor chips (e.g., dummy chips).

The second semiconductor chips 220 may include a plurality of second semiconductor chips 220a, 220b, 220c, and 220d disposed to be spaced apart from each other in a horizontal direction. The plurality of second semiconductor chips 220a, 220b, 220c, and 220d may be disposed on an upper interconnection structure 210. Each of the plurality of second semiconductor chips 220a, 220b, 220c, and 220d may be disposed on the corner portions of the central region CR, overlapping the first semiconductor chip 120 in a vertical direction. Each of the plurality of second semiconductor chips 220a, 220b, 220c, and 220d may include a first portion 220R1 disposed in the central region CR, and a second portion 220R2 disposed in an outer region PR. The plurality of second semiconductor chips 220 may be electrically connected to the upper interconnection structure 210 through bonding wires WB extending in a second direction (for example, a Y-axis direction when viewed from a plan view), but the bonding wires WB or additional bonding wires WB may extend in a first direction, and the present inventive concept is not limited to the bonding wires extending in a particular direction. The plurality of second semiconductor chips 220a, 220b, 220c, and 220d may be memory chips, and each of a plurality of second semiconductor chips 220a, 220b, 220c, and 220d may be a memory chip having a single layer structure, but the present inventive concept is not limited thereto, and may have a chip stack structure in which a plurality of memory chips are stacked in the vertical direction.

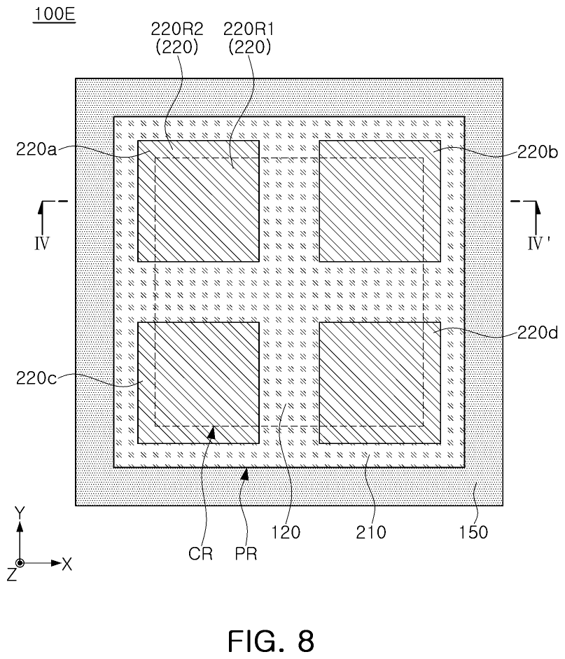

FIG. 8 is a top view of a semiconductor package 100E according to an example embodiment of the present inventive concept. FIG. 9 is a cross-sectional view of the semiconductor package 100E of FIG. 8, taken along line IV-IV′.

Referring to FIGS. 8 and 9, the semiconductor package 100E according to an example embodiment may have features the same as or similar to those described with reference to FIGS. 1 to 5, except that additional conductive bumps 225 are disposed between second semiconductor chips 220 and an upper interconnection structure 210. In addition, in some embodiments, the example of FIGS. 8 and 9 may not include a plurality of third semiconductor chips (e.g., dummy chips).

Chip connection pads 220P may be disposed on a lower portion of the second semiconductor chips 220, and upper mounting pads 212U may be disposed on an upper surface of the upper interconnection structure 210. The chip connection pads 220P and the upper mounting pads 212U may be aligned to correspond to each other. The conductive bumps 225 may be disposed between the chip connection pads 220P and the upper mounting pads 212U of the second semiconductor chips 220. The conductive bumps may electrically connect the chip connection pads 220P of the second semiconductor chips 220 to the upper mounting pads 212U of the upper interconnection structure 210. An underfill material 240 may cover at least a portion of each of the second semiconductor chips 220 and the conductive bumps 225, and may surround the conductive bumps 225, thereby protecting the conductive bumps 225 from physical impacts and chemical damage.

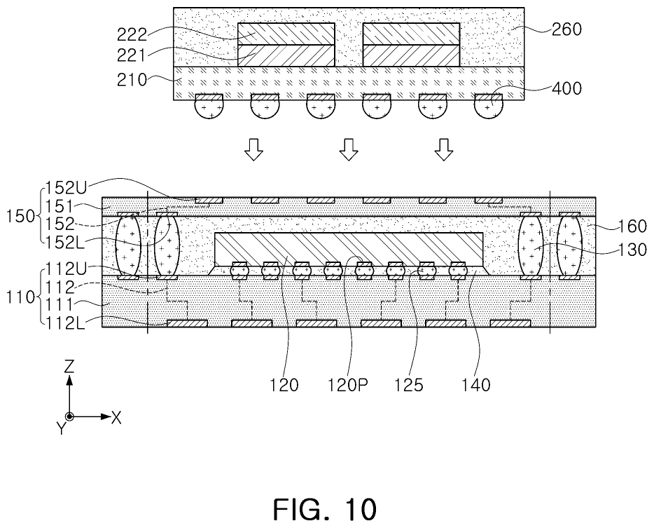

FIGS. 10 to 12 are cross-sectional views of a semiconductor package according to the related art, which may suffer from thermal expansion, warpage, and/or cracking issues.

FIGS. 10 to 12 are cross-sectional views of a process of manufacturing a semiconductor package according to the related art.

Referring to FIG. 10, a lower package may be formed to include a first lower interconnection structure 110, a first semiconductor chip 120 mounted on the first lower interconnection structure 110, connection structures 130 disposed around the first semiconductor chip 120, on the first lower interconnection structure 110, a first encapsulant 160 covering the first semiconductor chip 120 and the connection structures 130, and a second lower interconnection structure 150 disposed on the first encapsulant 160. The lower package, illustrated in FIG. 10, may have a structure before being divided into units along a sawing line. An upper package may be formed to include an upper interconnection structure 210, second semiconductor chips 220 mounted on the upper interconnection structure 210, and a second encapsulant 260 covering the second semiconductor chips 220, on the upper interconnection structure 210. In a subsequent process, the upper package may be disposed on the lower package. In the semiconductor package according to an example illustrated in FIG. 10, the second semiconductor chips 220 may be disposed in a region overlapping the first semiconductor chip 120 in a vertical direction.

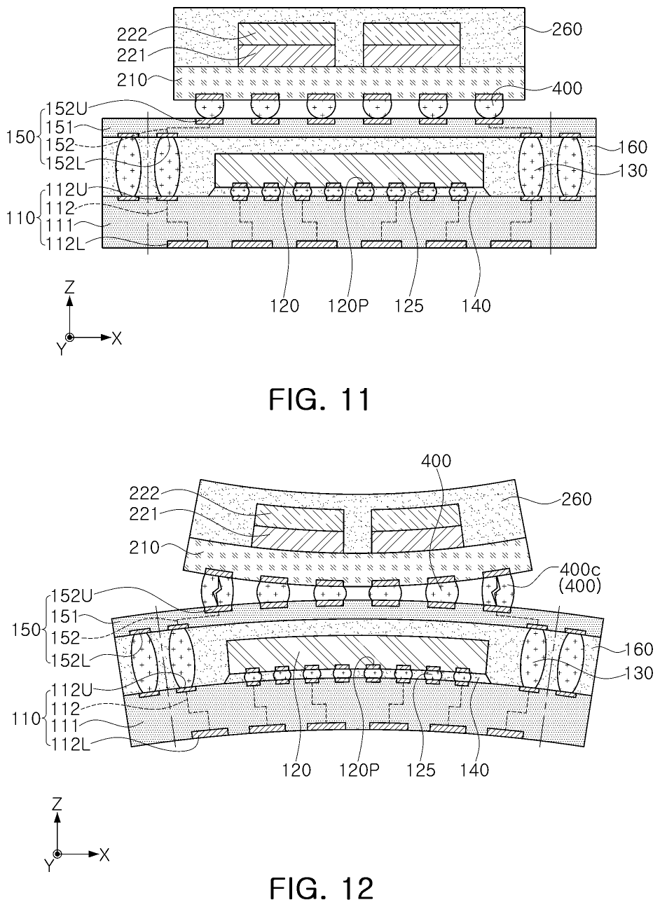

Referring to FIG. 11, a conductive material may be injected into a space between the lower package and the upper package, and reflow and curing processes may be performed thereon. Solder bumps 400 may be formed through the reflow and curing processes, and the lower package and the upper package may be electrically connected to each other through the solder bumps 400 disposed therebetween.

Referring to FIG. 12, in semiconductor packages according to the related art, a difference between degrees of expansion of the lower package and the upper package (caused by a difference between coefficients of thermal expansion of the lower and upper packages) may occur in a thermal cycle (TC) test and/or due to heating during actual usage. In one example, the lower package may have a convexly curved shape, e.g. with both ends curving downwards, and the upper package may have a concavely curved shape, e.g. with both ends curving upwards, but directions in which the lower and upper packages are curved are not limited thereto. Such cry warpage of the lower package and smile warpage of the upper package may stress the solder bumps 400 disposed between the lower package and the upper package, leading to cracks frequently forming in solder bumps 400c closest to a corner portion of the upper interconnection structure 210 and a corner portion of the first semiconductor chip 120, among the solder bumps 400c.

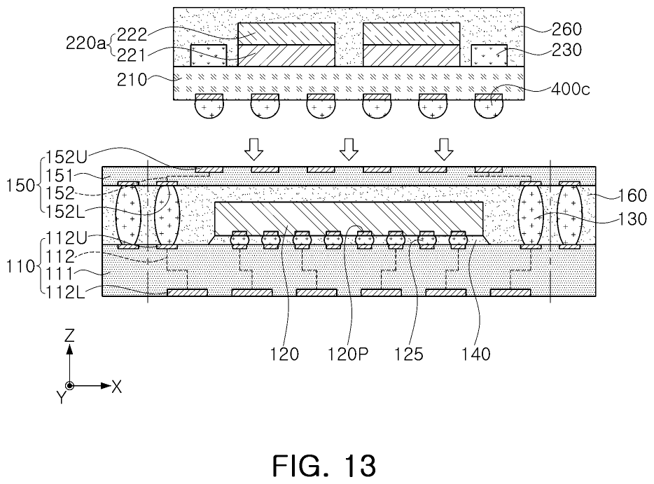

FIG. 13 is a cross-sectional view of a semiconductor package having improved reliability and longevity according to the present inventive concept.

Referring to FIG. 13, in order to address the issue described above with reference to FIGS. 10 to 12, a chip structure 231, overlapping the corner portion of the first semiconductor chip 120 in the vertical direction (e.g., when viewed from a plan view), may be disposed. In some examples, the chip structure may be a dummy chip, such as chip 230 described above. The chip structure 231 may be disposed to overlap at least a portion of the solder bump 400c disposed to be closest to the corner portion of the first semiconductor chip 120, among the solder bumps 400 disposed between the upper interconnection structure 210 and the second lower interconnection structure 150, in the vertical direction. According to aspects of the present inventive concept, the chip structure 231 may be disposed on the corner portion having a largest difference between degrees of deformation of the upper package and the lower package (e.g., at a location where the smile and cry warpages shown in FIG. 12 would cause the greatest stress), thereby alleviating the difference between degrees of thermal expansion of the upper and lower packages. For example, a coefficient of thermal expansion of chip structure 231 may be intermediate between those of the lower and upper packages, thereby alleviating the difference between coefficients of thermal expansion described above in the example of FIG. 12. Alternatively or additionally, the chip structure 231 may provide structural stability (e.g., rigidity), or the positioning of chip structure 231 may reduce the warpage (e.g., smile warpage) of the upper package. The chip structure 231 may be a dummy chip (e.g., a non-functional and/or electrically insulated memory chip or simply a silicon chip without any integrated circuit formed thereon), but the present inventive concept is not limited thereto, and may have a structure in which a functioning memory chip mounted on the upper package is shifted to overlap the corner portion of the first semiconductor chip 120 in the vertical direction.

According to example embodiments of the present inventive concept, a structure may be introduced in which an upper chip structure is disposed on a corner portion of a lower chip, thereby providing a semiconductor package less prone to stress-induced cracking, and having improved reliability and longevity.

While example embodiments have been shown and described above, it will be apparent to those skilled in the art that modifications and variations could be made without departing from the scope of the present invention as defined by the appended claims.

1. A semiconductor package including:
a first lower interconnection structure including a first lower interconnection layer;
a first semiconductor chip on the first lower interconnection structure, the first semiconductor chip electrically connected to the first lower interconnection layer;
connection structures disposed around the first semiconductor chip, the connection structures electrically connected to the first lower interconnection layer;
a first encapsulant covering at least a portion of each of the first semiconductor chip and the connection structures;
a second lower interconnection structure on the first encapsulant, the second lower interconnection structure including a second lower interconnection layer electrically connected to the connection structures;
an upper interconnection structure on the second lower interconnection structure, the upper interconnection structure including an upper interconnection layer;
solder bumps between the second lower interconnection structure and the upper interconnection structure, the solder bumps electrically connecting the second lower interconnection layer and the upper interconnection layer to each other;
a second semiconductor chip on the upper interconnection structure, the second semiconductor chip electrically connected to the upper interconnection layer;
a plurality of third semiconductor chips spaced apart from the second semiconductor chip in a horizontal direction, on the upper interconnection structure; and
a second encapsulant covering at least a portion of each of the second semiconductor chip and the plurality of third semiconductor chips,
wherein the first semiconductor chip has a first planar area,
wherein the second semiconductor chip has a second planar area, smaller than the first planar area,
wherein each of the plurality of third semiconductor chips has a third planar area, smaller than the second planar area,
wherein the upper interconnection structure has a central region overlapping the first semiconductor chip in a vertical direction, and an outer region disposed around the central region, and
wherein each of the plurality of third semiconductor chips has a first portion positioned in the central region, and a second portion positioned in the outer region.

2. The semiconductor package of claim 1, wherein
the second semiconductor chip includes a lower surface facing the upper interconnection structure, an upper surface opposite to the lower surface, and chip connection pads disposed on the upper surface, and
the chip connection pads are electrically connected to the upper interconnection layer through a bonding wire.

3. The semiconductor package of claim 1, wherein
the second semiconductor chip includes a lower surface facing the upper interconnection structure, and chip connection pads on the lower surface, and
wherein the chip connection pads are electrically connected to the upper interconnection layer through a conductive bump.

4. The semiconductor package of claim 3, further comprising:
an underfill material covering at least a portion of each of the second semiconductor chip and the conductive bump.

5. The semiconductor package of claim 1, wherein the first semiconductor chip is a logic chip, and the second semiconductor chip is a memory chip.

6. The semiconductor package of claim 1, wherein at least a portion of the second semiconductor chip does not overlap the first semiconductor chip in the vertical direction.

7. The semiconductor package of claim 1, wherein the plurality of third semiconductor chips include dummy chips electrically insulated from the upper interconnection layer.

8. The semiconductor package of claim 1, wherein at least some of the plurality of third semiconductor chips at least partially overlap at least some of the solder bumps in the vertical direction.

9. The semiconductor package of claim 1, further comprising:
external connection conductors disposed below the first lower interconnection structure.

10. The semiconductor package of claim 1, wherein:
the first lower interconnection structure comprises a first lower interconnection substrate;
the connection structures comprises connection substrates;
the second lower interconnection structure comprises a second lower interconnection substrate; and
the upper interconnection structure comprises an upper interconnection substrate.

11. A semiconductor package comprising:
a first lower interconnection structure including a first lower interconnection layer;
a first semiconductor chip disposed on the first lower interconnection structure;
connection structures disposed around the first semiconductor chip, the connection structures electrically connected to the first lower interconnection layer;
a second lower interconnection structure including a second lower interconnection layer electrically connected to the connection structures, on the first lower interconnection structure;
an upper interconnection structure including an upper interconnection layer and upper connection pads electrically connected to the upper interconnection layer;
a plurality of chip stacks disposed on the upper interconnection structure to be spaced apart from each other in a first direction, the plurality of chip stacks including chip connection pads; and
a bonding wire connecting, to each other, the upper connection pads and the chip connection pads adjacent to each other in a second direction intersecting the first direction,
wherein each of the plurality of chip stacks is disposed to be misaligned with the first semiconductor chip in at least one of the first direction and the second direction.

12. (canceled)

13. The semiconductor package of claim 11, wherein
the plurality of chip stacks includes a plurality of semiconductor chips stacked in a vertical direction, and
the semiconductor chips in each chip stack are stacked in a step configuration.

14. The semiconductor package of claim 11, wherein, in a plan view, the plurality of chip stacks are disposed on a first boundary defined by sides of the first semiconductor chip.

15. The semiconductor package of claim 11, further comprising:
a plurality of dummy chips disposed on the upper interconnection structure,
wherein, in the plan view, the plurality of dummy chips are disposed on a second boundary defined by vertices of the first semiconductor chip.

16. The semiconductor package of claim 15, wherein the plurality of dummy chips are spaced apart from the plurality of chip stacks in a horizontal direction.

17. The semiconductor package of claim 15, wherein a thickness of each of the plurality of dummy chips is greater than or equal to a thickness of a lowermost semiconductor chip, among each of the plurality of chip stacks.

18. (canceled)

19. A semiconductor package comprising:
a first lower interconnection structure;
a first semiconductor chip mounted on the first lower interconnection structure;
an encapsulant covering at least a portion of the first semiconductor chip, on the first lower interconnection structure;
a second lower interconnection structure disposed on the encapsulant;
an upper interconnection structure disposed on the second lower interconnection structure, the upper interconnection structure electrically connected to the second lower interconnection structure; and
a plurality of chips mounted on the upper interconnection structure,
wherein at least one chip, among the plurality of chips, partially overlaps a corner of the first semiconductor chip.

20. (canceled)

21. The semiconductor package of claim 19, wherein
the at least one chip, among the plurality of chips, is electrically insulated from the upper interconnection structure, and
a remaining chip, among the plurality of chips, is electrically connected to the upper interconnection structure.

22. The semiconductor package of claim 19, wherein the at least one chip, among the plurality of chips, is configured to reduce a degree of warpage of the upper interconnection structure or the semiconductor package.

23. The semiconductor package of claim 19, wherein:
the at least one chip, among the plurality of chips, has a coefficient of thermal expansion intermediate between coefficients of thermal expansion of the first lower interconnection structure and the upper interconnection structure; or
the at least one chip, among the plurality of chips, has a coefficient of thermal expansion intermediate between coefficients of thermal expansion of the second lower interconnection structure and the upper interconnection structure.
